(19) United States
(12) Patent Application Publication
(10) Pub. No.: US 2015/0001548 A1
(43) Pub. Date: Jan. 1, 2015

(54) LIGHT EMITTING CHIP

(71) Applicant: DISCO CORPORATION, Tokyo (JP)

(72) Inventors: Takashi Okamura, Tokyo (JP); Taro Arakawa, Tokyo (JP); Yuriko Yamagami, Tokyo (JP)

(21) Appl. No.: 14/316,006

(22) Filed: Jun. 26, 2014

(30) Foreign Application Priority Data
Jul. 1, 2013 (JP) 2013-137781

(51) Int. Cl. H01L 33/48; H01L 33/32

(52) U.S. Cl. CPC H01L 33/48; H01L 33/32
USPC 257/76

(57) ABSTRACT

The present invention provides a light emitting chip including a device chip having a sapphire base and a light emitting layer formed over the front surface of the sapphire base and a transparent member stuck to the back surface of the sapphire base by a transparent resin transmissive to emitted light from the light emitting layer. The transparent member is transmissive to emitted light from the light emitting layer. The transparent member is formed of a material having a lower refractive index than the sapphire base.

### BACKGROUND OF THE INVENTION

1. Field of the Invention

The present invention relates to a light emitting chip including a device chip in which a light emitting layer is formed.

2. Description of the Related Art

Light emitting devices including light emitting diode (LED), laser diode (LD), and so forth have been put into practical use. These light emitting devices normally include a light emitting chip having a device chip in which a light emitting layer that emits light by application of a voltage is formed. In manufacturing of this device chip, first an epitaxial layer (crystal layer) is grown as the light emitting layer in the respective areas partitioned by planned dividing lines in a lattice manner on a base for crystal growth. Thereafter, the base for crystal growth is divided along the planned dividing lines to be turned to individual pieces. Thereby, the device chips for individual light emitting chips are formed.

In the light emitting chip, in a device chip in which the light emitting layer that emits green or blue light is an InGaN-based material layer, generally sapphire is used as the base for crystal growth and an n-type GaN semiconductor layer, an InGaN light emitting layer, and a p-type GaN semiconductor layer are sequentially epitaxially grown over this sapphire base. Furthermore, an external lead-out electrode is formed for each of the n-type GaN semiconductor layer and the p-type GaN semiconductor layer.

A light emitting diode is formed by fixing the back surface side (sapphire base side) of this device chip to a lead frame and covering the front surface side (light emitting layer side) of the device chip by a lens member. For such a light emitting diode, enhancement in the luminance is considered as an important challenge and various methods for enhancing the light extraction efficiency have been proposed before (refer to e.g. Japanese Patent Laid-Open No. Hei 4-10670).

### SUMMARY OF THE INVENTION

Light generated in the light emitting layer by application of a voltage is emitted mainly from two major surfaces (front surface and back surface) of a layer stack including the light emitting layer. For example, the light emitted from the front surface of the layer stack (major surface on the lens member side) is extracted to the external of the light emitting diode via the lens member and so forth. Meanwhile, the light emitted from the back surface of the layer stack (major surface on the sapphire base side) travels in the sapphire base and part thereof is reflected at the interface between the sapphire base and the lead frame and so forth to return to the layer stack.

For example, if a thin sapphire base is used for the device chip for the purpose of enhancement in the processability in cutting and so forth, the distance between the back surface of the layer stack and the interface between the sapphire base and the lead frame is short. In this case, the ratio of light reflected at the interface between the sapphire base and the lead frame to return to the layer stack is higher than that when the sapphire base is thick. The layer stack absorbs light. Therefore, when the ratio of light that returns to the layer stack is higher as above, the light extraction efficiency of the light emitting diode is lower.

Therefore, an object of the present invention is to provide a light emitting ship having a novel configuration that allows enhancement in the light extraction efficiency.

In accordance with an aspect of the present invention, there is provided a light emitting chip including a device chip including a base and a light emitting layer formed over a front surface of the base and a transparent member stuck to a back surface of the base by a transparent resin transmissive to emitted light from the light emitting layer. The transparent member is formed of a material that is transmissive to emitted light from the light emitting layer and has a lower refractive index than the base.

According to this configuration, because the transparent member transmissive to light emitted from the light emitting layer is bonded to the back surface of the base of the device chip, the ratio of light reflected at the back surface of the base to return to the light emitting layer can be suppressed to a low ratio and the ratio of light that goes out of the side surface of the base and the transparent member can be increased. In addition, because the transparent member is formed of a material whose refractive index is lower than that of the base, the refraction angle of light that is incident on the transparent member and is refracted can be set larger than the incident angle of light transmitted through the base to the transparent member. Due to this, the traveling direction of the light that is incident on the transparent member and is refracted can be set to such a direction that the ratio of light that goes out of the transparent member is increased. Thus, the ratio of light that returns to the light emitting layer due to reflection can be suppressed to a low ratio and the light extraction efficiency can be enhanced. Furthermore, even when the base is made thin, reflected light can be made incident on a position out of the light emitting layer according to the thickness of the transparent member. Thus, a thin base can be used without lowering the light extraction efficiency and high processability attributed to the thin base for crystal growth can be kept.

Preferably, the base of the device chip is sapphire, and the light emitting layer may be formed of a GaN semiconductor layer. According to this configuration, the light extraction efficiency can be enhanced in a light emitting chip that emits blue or green light.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view schematically showing a configuration example of a light emitting diode according to a first embodiment;

FIG. 2 is a schematic sectional view showing how light is emitted in the light emitting diode according to the first embodiment;

FIG. 3 is a schematic sectional view showing how light is emitted in a light emitting diode according to a comparative structure;

FIG. 4A is a perspective view schematically showing a configuration example of a light emitting diode according to a second embodiment;

FIG. 4B is a schematic sectional view of the light emitting diode according to the second embodiment;

FIG. 5A is a schematic sectional view of a working example and comparative examples 1 and 2; and

FIG. 5B is a graph showing a measurement result of the total radiant flux of the working example and comparative examples 1 and 2.

### DETAILED DESCRIPTION OF THE PREFERRED EMBODIMENTS

### First Embodiment

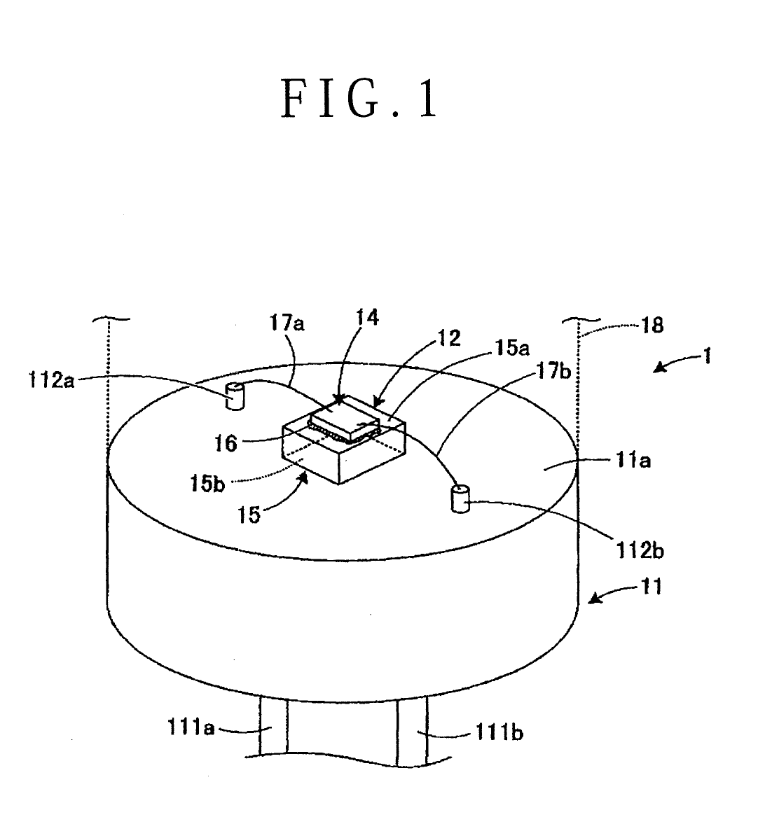

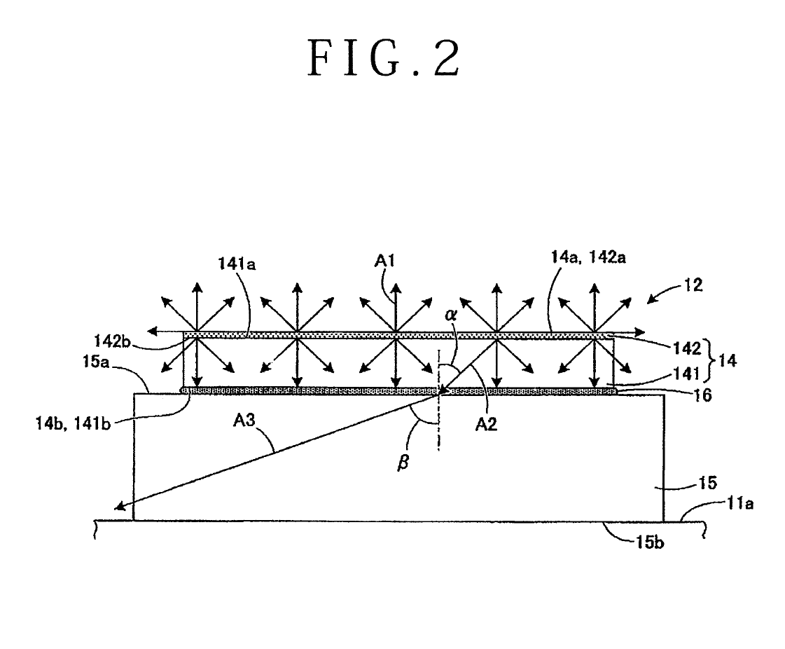

Embodiments of the present invention will be described below with reference to the accompanying drawings. FIG. 1 is a perspective view schematically showing a configuration example of a light emitting diode according to a first embodiment. FIG. 2 is a schematic sectional view showing how light is emitted from a light emitting chip of the light emitting diode according to the first embodiment. As shown in FIG. 1, a light emitting diode 1 includes a lead frame 11 serving as a base component and a light emitting chip 12 supported and fixed by the lead frame 11.

The lead frame 11 is formed into a circular column shape by a material such as a metal and two lead members 111a and 111b having electrical conductivity are provided on the side of the back surface equivalent to one bottom surface. The lead members 111a and 111b are insulated from each other and function as the anode and cathode, respectively, of the light emitting diode 1. The lead members 111a and 111b are connected to an external power supply (not shown) via wiring (not shown) or the like.

On a front surface 11a equivalent to the other bottom surface of the lead frame 11, two connection terminals 112a and 112b insulated from each other are disposed at a predetermined interval. The connection terminal 112a is connected to the lead member 111a inside the lead frame 11. The connection terminal 112b is connected to the lead member 111b inside the lead frame 11. Therefore, the potentials of the connection terminals 112a and 112b are equivalent to the potentials of the lead members 111a and 111b, respectively.

The light emitting chip 12 is disposed on the front surface 11a of the lead frame 11 and between the connection terminal 112a and the connection terminal 112b. As shown in FIG. 2, the light emitting chip 12 has a device chip 14 and a transparent member 15 bonded to a back surface 14b of this device chip 14 by a transparent resin 16. The device chip 14 includes a sapphire base 141 having a rectangular shape as its planar shape and a layer stack 142 provided on a front surface 141a of the sapphire base 141. The layer stack 142 includes plural semiconductor layers formed by using GaN-based semiconductor materials (GaN semiconductor layers).

The layer stack 142 is formed by sequentially epitaxially growing an n-type semiconductor layer (e.g. n-type GaN layer), in which electrons are the majority carriers, a semiconductor layer (e.g. InGaN layer) to serve as a light emitting layer, and a p-type semiconductor layer (e.g. p-type GaN layer), in which holes are the majority carriers. Furthermore, on the sapphire base 141, two electrodes (not shown) that are connected to the n-type semiconductor layer and the p-type semiconductor layer, respectively, and apply a voltage to the layer stack 142 are formed. These electrodes may be included in the layer stack 142.

The transparent member 15 is formed of a material transmissive to light emitted from the light emitting layer. In the present embodiment, the transparent member 15 is formed of glass (e.g. soda glass or borosilicate glass) as a material having a lower refractive index than the sapphire base 141. As the refractive index of the sapphire base 141, e.g. 1.7 can be cited. As the refractive index of the glass, e.g. 1.5 can be cited. If a base is formed by another material instead of the sapphire base 141 in the device chip 14, the transparent member 15 is formed by a material having a reflective index lower than that of the base. The area of a front surface 15a of the transparent member 15 is larger than that of a back surface 141b of the sapphire base 141. Furthermore, it is preferable for the transparent member 15 to have a thickness equivalent to or larger than that of the sapphire base 141. The transparent resin 16 is formed of a resin material, such as a die bonding agent, transmissive to light emitted from the light emitting layer. It is provided on the whole of the back surface 14b of the device chip 14 and sticks the back surface 14b of the device chip 14 to the front surface 15a of the transparent member 15.

The two connection terminals 112a and 112b provided on the lead frame 11 are connected to the two electrodes of the light emitting chip 12 via lead wires 17a and 17b, respectively, having electrical conductivity. Due to this, the voltage of the power supply connected to the lead members 111a and 111b is applied to the layer stack 142. When the voltage is applied to the layer stack 142, electrons flow from the n-type semiconductor layer into the semiconductor layer serving as the light emitting layer and holes flow from the p-type semiconductor layer into it. As a result, the recombination of the electrons and the holes occurs in the semiconductor layer serving as the light emitting layer and light having a predetermined wavelength is emitted. In the present embodiment, because the semiconductor layer serving as the light emitting layer is formed by using a GaN-based semiconductor material, blue or green light corresponding to the band gap of the GaN-based semiconductor material is emitted.

A dome-shaped lens member 18 covering the side of a front surface 14a of the device chip 14 is attached to the circumferential edge of the side of the front surface 11a of the lead frame 11. The lens member 18 is formed of a material, such as a resin, having a predetermined refractive index and refracts the light emitted from the layer stack 142 of the device chip 14 to guide the light to the external of the light emitting diode 1 along predetermined directions. In this manner, the light emitted from the device chip 14 is extracted to the external of the light emitting diode 1 via the lens member 18.

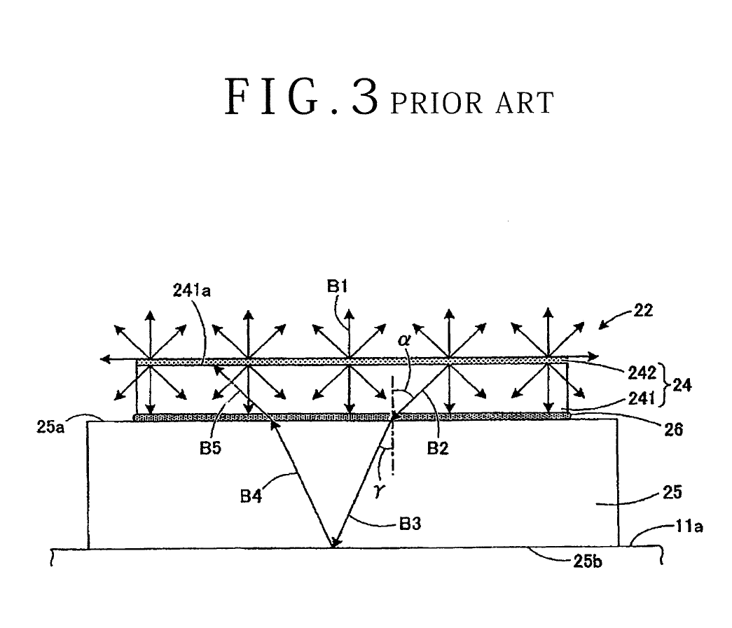

Next, description will be made about a luminance improvement effect by the light emitting diode 1 according to the first embodiment with reference to a light emitting diode according to a comparative structure of FIG. 3. FIG. 3 is a schematic sectional view showing how light is emitted from a light emitting chip of the light emitting diode according to the comparative structure for making a comparison with the first embodiment. The light emitting diode according to the comparative structure has a configuration in common with the light emitting diode 1 according to the first embodiment except for that the transparent member is different. Specifically, a transparent member 25 according to the comparative structure is formed of a material having a higher refractive index than a sapphire base 241. Furthermore, a device chip 24 including the sapphire base 241 having a rectangular shape as its planar shape and a layer stack 242 provided on a front surface 241a of the sapphire base 241 is bonded to the transparent member 25 by a transparent resin 26.

As shown in FIG. 2, in the light emitting diode 1 according to the first embodiment (see FIG. 1), light generated in the semiconductor layer serving as the light emitting layer is emitted mainly from a front surface 142a of the layer stack 142 (i.e. the front surface 14a of the device chip 14) and a back surface 142b. The light emitted from the front surface 142a of the layer stack 142 (e.g. an optical path A1) is extracted to the external of the light emitting diode 1 via the lens member 18 (see FIG. 1) and so forth as described above. On the other hand, e.g. light emitted from the back surface 142b of the layer stack 142 to travel on an optical path A2 is incident at an incident angle α on the back surface 14b of the device chip 14, which is the interface between the sapphire base 141 and the transparent member 15, and is transmitted through the transparent member 15 (optical path A3). Because the refractive index of the transparent member 15 is lower than that of the sapphire base 141, the light traveling on the optical path A3 is refracted when being incident on the transparent member 15 and a refraction angle β thereof is larger than the incident angle α of the optical path A2. Thus, the traveling direction of the light traveling on the optical path A3 is closer to the horizontal direction in FIG. 2 compared with the light traveling on the optical path A2 and the light traveling on the optical path A3 is incident on a side surface of the transparent member 15 to be emitted to the external.

In contrast, as shown in FIG. 3, although optical paths B1 and B2 of a light emitting chip 22 according to the comparative structure are the same as the optical paths A1 and A2 of the light emitting chip 12 according to the first embodiment and the respective incident angles α of the optical paths B2 and A2 are also the same angle, light that is transmitted through the transparent member 25 and travels on an optical path B3 has a different traveling direction from the light traveling on the optical path A3 in the first embodiment. Specifically, a refraction angle γ of the light traveling on the optical path B3 is smaller than the incident angle α of the optical path B2 and is smaller than the refraction angle β of the optical path A3 in the first embodiment. Therefore, the traveling direction of the light traveling on the optical path B3 is closer to the vertical direction in FIG. 3 compared with the light traveling on the optical path B2. The light traveling on the optical path B3 is reflected at the front surface 11a of the lead frame 11 (optical path B4) and is incident on the sapphire base 241 of the device chip 24 (optical path B5). The light traveling on the optical path B5 is transmitted through the sapphire base 241 and then incident on the layer stack 242 to be absorbed. Thus, the light cannot be extracted to the external.

As described above, according to the light emitting diode 1 in accordance with the first embodiment, the refractive index of the transparent member 15 is lower than that of the sapphire base 141 and thus light that is emitted from the layer stack 142 and travels as on the optical path A2 can be refracted by the transparent member 15 to travel as on the optical path A3 and be extracted to the external. Therefore, for the light traveling as on the optical path A2, the ratio of light reflected at the front surface 11a of the lead frame 11 to return to the layer stack 142 can be suppressed to a low ratio compared with the light traveling as on the optical path B2 in the comparative structure. Due to this, the ratio of light that goes out of the transparent member 15 can be made high. Thus, the light extraction efficiency can be enhanced and improvement in the luminance can be achieved.

The sapphire base is hard and not easy to process and therefore it is preferable to use a thin sapphire base to enhance the processability. In the above-described light emitting diode 1, the light extraction efficiency can be kept high by the transparent member 15 even when the thickness of the sapphire base 141 is reduced. That is, there is no need to increase the thickness of the sapphire base 141 for keeping the light extraction efficiency to sacrifice the processability.

### Second Embodiment

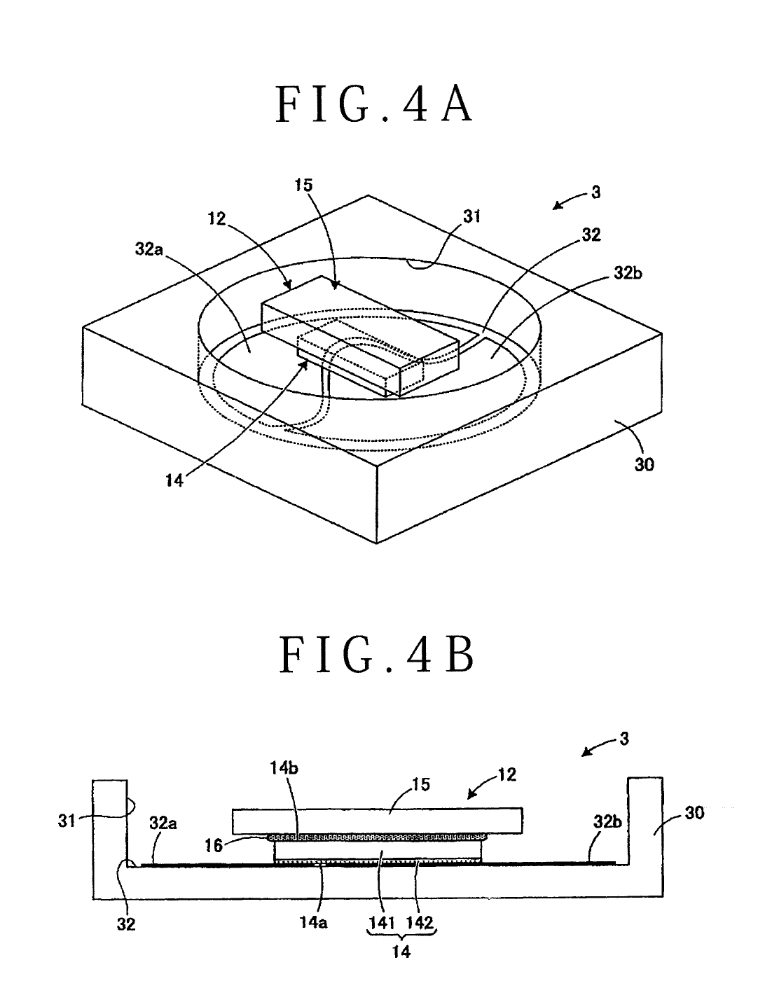

A second embodiment will be described below. In the second embodiment, constituent elements in common with the first embodiment are given the same numerals and description thereof is omitted. FIG. 4A is a perspective view schematically showing a configuration example of a light emitting diode according to the second embodiment and FIG. 4B is a schematic sectional view of the light emitting diode according to the second embodiment. As shown in FIGS. 4A and 4B, a light emitting diode 3 according to the second embodiment is obtained by supporting and fixing the light emitting chip 12 on a mounting surface 32 formed at a bottom surface in a recess 31 of a package 30. On the mounting surface 32, two connection electrodes 32a and 32b insulated from each other are disposed at a predetermined interval.

The light emitting chip 12 of the second embodiment includes the device chip 14 and the transparent member 15 bonded by the transparent resin 16 as with the light emitting chip 12 of the first embodiment and is so fixed that its vertical direction is inverted from the first embodiment. Electrodes (not shown) provided on the front surface 14a of the device chip 14 in the second embodiment are formed by protrusion-shaped terminals called bumps. They are connected to the connection terminals 32a and 32b through supporting and fixing of the front surface 14a of the device chip 14 on the mounting surface 32, so that the light emitting chip 12 is mounted by flip-chip mounting.

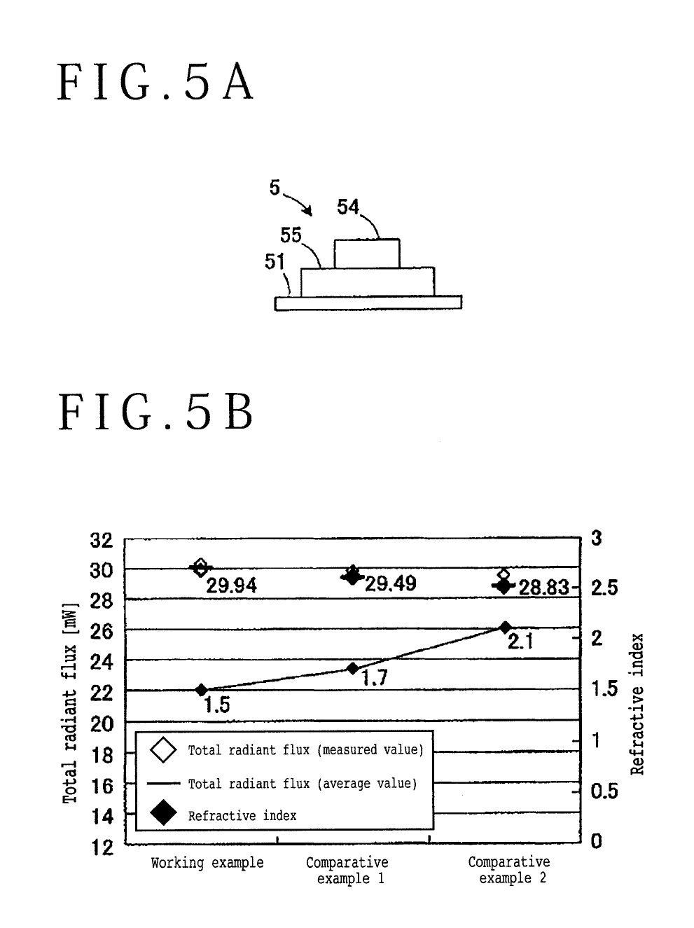

Next, an experiment carried out in order to check the luminance improvement effect of the light emitting diodes according to the above-described respective embodiments will be described. In this experiment, a light emitting diode 5 with a configuration shown in FIG. 5A was fabricated as a working example and comparative examples 1 and 2. The light emitting diode 5 was formed with a mounting board 51, a transparent member 55 bonded to the mounting board 51 with the intermediary of a transparent resin (not shown), and a device chip 54 bonded to the transparent member 55 with the intermediary of the transparent resin (not shown).

The transparent member 55 was formed to have an area (vertical×horizontal) of 0.8 mm×0.8 mm as the area of the front surface and back surface and have a thickness of 150 μm. The material of the transparent member 55 was made different for each of the working example and comparative examples 1 and 2. As the transparent member 55 of the working example, glass with a refractive index of 1.5 and transmittance of 97.25% was used. As the transparent member 55 of comparative example 1, sapphire with a refractive index of 1.7 and transmittance of 95.49% was used. As the transparent member 55 of comparative example 2, LT (lithium tantalite) with a refractive index of 2.1 and transmittance of 91.89% was used. To obtain the transmittance, the light emitting diode in which the device chip 54 was mounted on the mounting board 51 was made to emit light and light transmitted through the transparent member 55 was measured. As the transmittance, a percentage calculated by regarding the value obtained by directly measuring the light of this light emitting diode as the criterion was employed.

In all of the working example and comparative examples 1 and 2, the light emitting chip 54 having the same specifications as those of the device chip 14 of the first embodiment (see FIG. 2) was used. Specifically, the light emitting chip 54 was obtained by dividing a 2-inch wafer (made by Tekcore Co., Ltd.) to turn it into device chips. As the light emitting chip 54, a chip was employed in which a layer stack including a light emitting layer formed of a GaN semiconductor layer was formed on a sapphire base having an area (vertical×horizontal) of 7.975 mm×7.725 mm as the area of the front surface and back surface. Furthermore, in all of the working example and comparative examples 1 and 2, a die bonging agent (KER-M2 made by Shin-Etsu Chemical Co., Ltd.) transmissive to light was used as the transparent resin (not shown).

In this experiment, the total radiant flux of the light emitting diodes 5 of the working example and comparative examples 1 and 2 was measured. Specifically, the total value of the intensity (power) of all light radiated from each light emitting diode 5 was measured (measuring instrument: LX4651C made by Teknologue Co., Ltd.). FIG. 5B is a graph showing the measurement result. In FIG. 5B, the ordinate indicates the total radiant flux (mW) or refractive index of each light emitting diode.

As shown in FIG. 5B, in the working example, the total radiant flux as the intensity of light is higher by 0.45 to 1.11 mW than that of comparative examples 1 and 2 and the light extraction efficiency can be enhanced. Furthermore, from the result of FIG. 5B, a tendency could be confirmed that the total radiant flux became higher and the light extraction efficiency became higher when the refractive index of the transparent member 55 became lower.

The present invention is not limited to the above-described embodiments and can be carried out with various changes. The sizes, shapes, and so forth of constituent elements in the above-described embodiments are not limited to those illustrated in the accompanying drawings and can be arbitrarily changed within such a range as to exert effects of the present invention. Besides, the present invention can be carried out with arbitrary changes without departing from the scope of the object of the present invention.

For example, in the above-described embodiments, the device chip 14 using a sapphire base and a GaN-based semiconductor material is exemplified. However, the base for crystal growth and the semiconductor material are not limited to the embodiments. For example, a GaN substrate may be used as the base for crystal growth. Although it is preferable to reduce the thickness of the base for crystal growth, such as a sapphire base, to enhance the processability, the base for crystal growth does not necessarily need to be thin.

Furthermore, although the layer stack 142 in which an n-type semiconductor layer, a semiconductor layer that emits light, and a p-type semiconductor layer are sequentially provided is exemplified in the above-described embodiments, the configuration of the layer stack 142 is not limited thereto. It is enough for the layer stack 142 to be so configured as to be capable of at least emission of light through the recombination of electrons and holes.

In addition, the device chip 14 may be a device chip that emits infrared light (AlGaAs, GaAsP, or the like). In this case, the same effects as those of the above-described embodiments are obtained by forming the transparent member 15 by a material transmissive to infrared light. Moreover, the same effects as those of the above-described embodiments are obtained also when the device chip 14 emits ultraviolet light and the transparent member 15 is formed by a material transmissive to ultraviolet light.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A light emitting chip comprising:
a device chip including a base and a light emitting layer formed over a front surface of the base; and
a transparent member stuck to a back surface of the base by a transparent resin transmissive to emitted light from the light emitting layer,
wherein the transparent member is formed of a material that is transmissive to emitted light from the light emitting layer and has a lower refractive index than the base.

2. The light emitting chip according to claim 1, wherein the base of the device chip is composed of sapphire and the light emitting layer is formed of a GaN semiconductor layer.
